(19) United States
(12) Patent Application Publication
(10) Pub. No.: US 2004/0018716 A1
(43) Pub. Date: Jan. 29, 2004

(54) Semiconductor device and production method therefor

(76) Inventors: Hideyuki Kitou, Kanagawa (JP); Toshiaki Hasegawa, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 10/296,864

(22) PCT Filed: Apr. 3, 2002
(86) PCT No.: PCT/JP02/03357

(30) Foreign Application Priority Data
Apr. 5, 2001 (JP) 2001107505

(51) Int. Cl. H01L 21/4763; H01L 23/48; H01L 23/52; H01L 29/40

(52) U.S. Cl. 438/623; 257/759; 257/760; 438/624

(57) ABSTRACT

A semiconductor device formed of an insulation layer having at least a laminated portion in which a first insulation film made of silicon oxide film and a second insulation film made of organic insulation film are laminated on each other, wherein said semiconductor device has a silicon oxide film structure in which moisture absorption is limited, said structure having characteristics showing that a ratio S_{I}/S_{II} of area integrations S_{I} and S_{II} of a desorption gas spectrum by ion current measurement of the temperature programmed desorption mass analysis measurement based on mass 18 relating to the laminated structure of the silicon oxide film and the organic insulation film and a single layer structure of the silicon oxide film is not less than 1 or not more than 1.5. With this structure, problems of the semiconductor device having the insulation film or metal wiring in the semiconductor device having the insulation film structure in which the silicon oxide film and organic insulation film are laminated on each other that characteristics are deteriorated and peeling off is generated are solved.

### TECHNICAL FIELD

The present invention relates to a semiconductor device which is suitably applied to a semiconductor device having a multi-layer wiring structure and to a manufacturing method of the semiconductor device. More particularly, the invention improves electric characteristics and mechanical characteristics of an wiring structure portion.

### BACKGROUND ART

Conventionally, in a multi-layer wiring structure in an LSI (large-scale integration), an SiO film by plasma CVD (Chemical Vapor Deposition) method is normally used as an interlayer insulation film, and as a metal wiring, an Al alloy wiring is used.

However, as requirements for a finer and faster LSI have increased, metal wiring using the Al alloy can not sufficiently ensure high reliability and low resistance.

To solve this problem, Cu wiring technique which has excellent resistance against electromigration and low resistance compared with the Al alloy has been the focus of attention, and the Cu wiring has been studied to bring it into practical use.

Further, due to requirements for a finer and faster LSI, reduction of parasitic capacitance between wires is required. For this purpose, attempts have been made so that an insulation film between metal wirings is comprised of an insulation film of low specific inductivity k, e.g. k≦3.0.

Examples of the low specific inductivity insulation film are an SiOC film by plasma CVD method, an organic insulation film, e.g., polyaryl ether, and the like.

However, since it is difficult to work the SiOC film by etching, it is desired to use an organic insulation film, e.g., polyaryl ether which is easily be worked.

As an wiring structure for realizing low specific inductivity of the insulation film, a so-called full low specific inductivity wiring structure and a so-called hybrid wiring structure have been proposed.

FIG. 15 is a schematic sectional view of the full low specific inductivity wiring structure, and FIG. 16 is a schematic sectional view of an wiring structure using the hybrid structure.

In these wiring structures, a wiring groove 51 of a pattern corresponding to a wiring pattern is formed in an interlayer insulation film 50, and on the bottom of the wiring groove 51, a contact hole 51c is formed at a predetermined section that should come into contact with a wire, an electrode (not shown) and the like of a lower layer. Metal, e.g. Cu is filled into the wiring groove 51 and the contact hole 51c formed at a predetermined section thereof, and a metal wiring 52 having a contact portion 52c is formed.

As shown in FIG. 15, in this wiring structure, in the full low specific inductivity wiring structure, both an inter-wirings insulation film 50A and an inter-contact section insulation film 50B of the interlayer insulation film 50 is comprised of a low specific inductivity insulation layer which is an organic film.

A stopper layer 53 made of silicon oxide film is formed on the inter-contact portion insulation film 50B at a time of forming the wiring groove 51 in the inter-wirings insulation film 50A. A stopper layer 54 made of silicon oxide film that serves as a stopper in a polishing process of a surface flattening processing of the metal wiring 52 is formed on the inter-wirings insulation film 50A.

A barrier insulation layer 55 made of an SiN film, for example, is formed under the insulation film 50B for preventing dispersion when wiring of a lower layer is made of Cu. Further, when the metal wire is also Cu, a barrier metal layer 56 for preventing dispersion thereof is formed on an inner surface of the wiring groove 51 including the inside of the contact hole 51c.

On the other hand, in the hybrid structure, as shown in FIG. 16, only the inter-wirings insulation film 50A comprises a low specific inductivity insulation layer made of an organic film, and the inter-contact portion insulation film 50B comprises SiO, SiOF or the like of an silicon oxide film showing relatively high specific inductivity. In FIG. 16, portions corresponding to those of FIG. 15 are attached with the same symbols, and redundant explanation is omitted.

According to the full low specific inductivity wiring structure shown in FIG. 15, it is possible to also reduce the parasitic capacitance between adjacent contact portions (only one contact portion is shown in FIG. 15).

However, the organic film is inferior in thermal conductivity to silicon oxide film, and inferior in heat resistance. Therefore, when the semiconductor device is operated, heat accumulates inside the wiring structure, and reliability with regard to the operation of a semiconductor device is affected.

The hybrid structure has higher reliability of a semiconductor device.

However, regardless of the above mentioned full low specific inductivity or hybrid structure, when an organic insulation film is utilized as an insulation film or Cu, for example, is used as metal wiring, deterioration in the film quality of the insulation film or the metal wiring is inevitable due to heat treatment and the like of the manufacturing process where electric-characteristic deterioration occurs and peeling-off of the film is caused by mechanical-characteristic deterioration, so that problems of reliability, yield and the like will occur.

### DISCLOSURE OF THE INVENTION

The present invention had found by investigation that the above-described problems were ascribable to silicon oxide film, and this problem could be improved by specifying the characteristics of the silicon oxide film. Based on this fact, the present invention provides a semiconductor device capable of solving the various problems and provides a manufacturing method of such a semiconductor device.

The present invention provides a semiconductor device in which an insulation layer having at least a laminated portion comprising a first insulation film made of a silicon oxide film and a second insulation film made of organic insulation film being laminated on each other is formed, wherein the silicon oxide film is comprised of silicon oxide subjected to humidity absorption limitation having a characteristic that a ratio S₁/S₁₁ of respective area integrations of S₁ and S₁₁ of desorption gas spectrum at temperatures of 0. to 450. by ion electric current measurement of the temperature programmed desorption mass analysis measurement based on mass 18 relating to each of the laminated structure comprised of the silicon oxide film and organic insulation film and the single layer structure made of silicon oxide film is not less than 1 or not more than 1.5.

As a measuring device of this temperature programmed desorption mass analysis measurement, WA1000S manufactured by Denshi Kagaku (ESCO) was used.

The present invention also provides a manufacturing method of a semiconductor device comprising a film forming step of a first insulation film made of silicon oxide film by a chemical vapor deposition (CVD); and a film forming step of a second insulation film made of organic insulation film, wherein the first insulation film is formed under film forming condition that, a ratio S₁/S₁₁ of respective area integrations of S₁ and S₁₁ of a desorption gas spectrum at temperatures of 0. to 450. by ion electric current measurement of the temperature programmed desorption mass analysis measurement based on mass 18 relating to each of the laminated structure comprised of the silicon oxide film and organic insulation film and the single layer structure made of silicon oxide is not less than 1 or not more than 1.5,

The above laminated insulation layer constitutes an interlayer insulation layer between metal wirings of Cu in the multi-layer wiring structure.

According to the semiconductor device and its manufacturing method of the present invention, it was possible to effectively avoid the generation of deterioration of characteristics, i.e., degeneration and peeling off in the organic insulation film and metal wiring.

That is, in the case of silicon formed of silicon oxide film (first insulation film), especially by CVD, it was found that desorption gas was generated, thereby affecting the organic insulation film (second insulation film) and the characteristics of metal wiring of Cu.

This desorption gas is mainly water (H₂O) or oxygen (O₂). When heat exceeding 300° C. is added to the organic insulation film in the manufacturing process of the semiconductor device, for example, the organic insulation film is prone to react with the water and oxygen, desorpton of gas becomes remarkable, the film quality of the organic insulation film or Cu is deteriorated and more particularly, crack is generated and film peeling off is generated.

By comparison, according to the present invention, when silicon oxide film that is in contact with the organic film is formed, formation of film is carried out to restrain the above mentioned desorption of gas, and especially, the characteristics of film formation and film forming conditions are set such that S_{I}/S_{II} is set to not less than 1 or not more than 1.5, and at that figures, the deterioration of the film quality, more particularly, generation of crack was avoided.

### BRIEF DESCRIPTION OF THE DRAWINGS

FIG. 1 is a schematic sectional view of an essential portion of one example of a semiconductor device of the present invention,

FIGS. 2A to 2C are process charts (part 1) of one example of a manufacturing method of the invention,

FIGS. 3A to 3C are process charts (part 2) of one example of the manufacturing method of the invention,

FIGS. 4A and 4B are process charts (part 3) of one example of a manufacturing method of the invention,

FIGS. 5A and 5B are process charts (part 4) of one example of a manufacturing method of the invention,

FIG. 6 is a schematic block diagram of one example of a plasma CVD apparatus used in the manufacturing method of the invention,

FIGS. 7A and 7B are schematic sectional view of samples 1 and 2 used for stipulating moisture absorbing characteristics of a silicon oxide film of the present invention,

FIG. 8 is a desorption gas spectrum diagram of samples 1 and 2 in an embodiment of the invention,

FIG. 9 is a desorption gas spectrum diagram of samples 1 and 2 in the embodiment of the invention,

FIG. 10 is a desorption gas spectrum diagram of samples 1 and 2 in the embodiment of the invention,

FIG. 11 is a desorption gas spectrum diagram of samples 1 and 2 in the embodiment of the invention,

FIG. 12 is a desorption gas spectrum diagram of samples 1 and 2 in a comparative example,

FIG. 13 is a desorption gas spectrum diagram of samples 1 and 2 in a comparative example,

FIG. 14 is a desorption gas spectrum diagram of samples 1 and 2 in a comparative example,

FIG. 15 is a schematic sectional view of an essential portion of a full low specific inductivity structure of a conventional multi-layer wiring structure, and

FIG. 16 is a schematic sectional view of an essential portion of a hybrid wiring structure of a conventional multi-layer wiring structure.

### BEST MODE FOR CARRYING OUT THE INVENTION

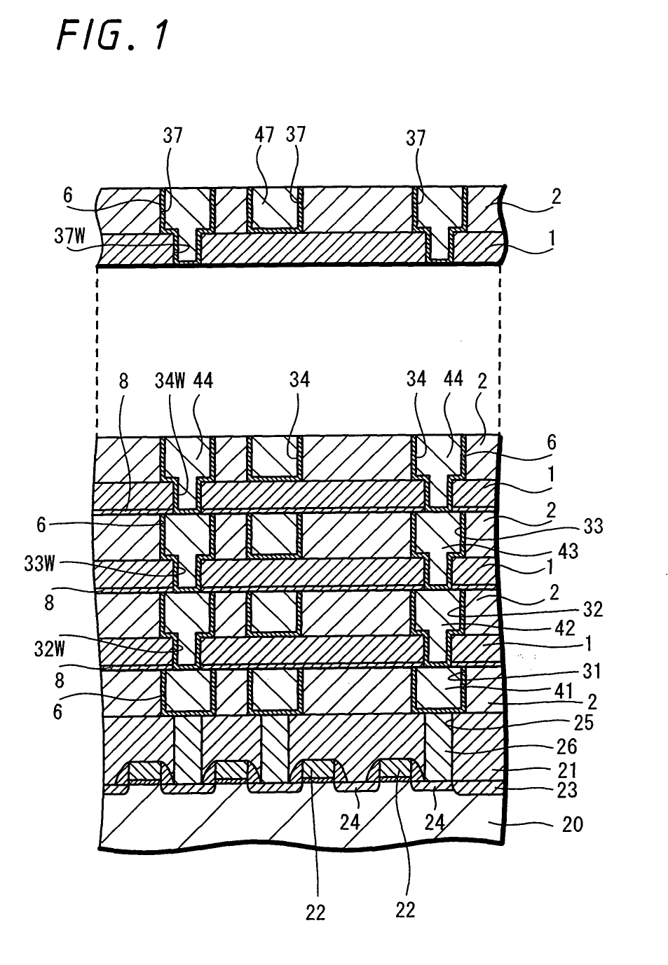

FIG. 1 is a schematic sectional view of one example of an embodiment of the present invention. However, this invention is not limited to the embodiment and this example.

FIG. 1 shows a semiconductor device having a semiconductor substrate 20 on which a multi-layer wiring structure is formed.

This example is for manufacturing a semiconductor device having the multi-layer wiring structure on the semiconductor substrate 20, where required circuit elements 22 is formed, e.g. a silicon semiconductor substrate.

This multi-layer wiring structure has insulation layers each comprising a first insulation film 1 made of silicon oxide film and a second insulation film 2 made of low organic insulation film with low specific inductivity k, and the first insulation film 1 and the second insulation film 2 are laminated on each other.

A silicon oxide film of the first insulation film 1 may be made of SiO, SiOF or, other than those, e.g. SiOC, although it is inferior in workability.

An organic insulation film of the second insulation film 2 is composed of, e.g. polyaryl ether SiLK (produced by Dow Chemical Co., name of article), an aromatic polymer, e.g. FLARE (Honeywell Co., name of article), a fluorocarbon polymer or the like, each having specific inductivity k=3.0 or smaller.

A semiconductor circuit element 22 is formed on one main surface of the semiconductor substrate 20, and an isolation insulation layer 23 made of STI (Shallow Trench Isolation) is formed between the circuit elements which should be isolated from each other.

In this example, when a semiconductor circuit element 22 by an insulation gate type transistor (MOS) is formed, its source or drain region (S/D region, hereinafter) 24 is formed, and required wires of multi-layer wiring structure are electrically contacted to a predetermined S/D region 24 from which wire is pulled out.

An insulation layer (on-substrate insulation layer, hereinafter) 21 formed on the semiconductor substrate 20 is formed of the first insulation film 1, for example, and a through hole 25 is bored on a position from which a wire is pulled out of the circuit element 22. A conductive plug 26 by tungsten (W) is charged into the through hole.

In this manner, the conductive plug 26 is brought into contact with a predetermined, e.g. S/D region 24 directly, or with an electrode or a wire (not shown) formed on the S/D region 24.

The second insulation film 2 comprising an organic insulation film is formed on the on-substrate insulation layer 21. A first wiring groove 31 is formed into a desired pattern into which first metal wiring 41 is to be charged. The first wiring groove 31 passes through the second insulation film 2. In this manner, the first metal wiring 41 is brought into contact with the conductive plug 26 at a predetermined portion.

The first insulation film 1 and the second insulation film 2 are laminated on the second insulation film 2 in which the first metal wiring 41 is formed, thereby forming the interlayer insulation film. A second wiring groove 32 having a predetermined pattern to which the second metal wiring 42 is to be charged is formed in the interlayer insulation film such as to pass through the second insulation film. A metal wiring 42 is charged into a portion of the wiring groove 32. A through hole 32w which is brought into communication with a predetermined portion of the first metal wiring 41 is formed, and the second metal wiring 42 and the first metal wiring 41 are brought into contact with each other.

In FIG. 1, the same structure as that of the second metal wiring 42 is employed, and third to seventh metal wirings 43 to 47 are sequentially formed on the interlayer insulation layer on which the first insulation films 1 and 2 are laminated, respectively.

In the structure shown in FIG. 1, metal wirings 41 to 47 are formed of Cu in which dispersion is generated. A barrier metal layer 6 made of, for example, TaN or TiN which prevents the dispersion includes through holes 32w to 37w and is formed on the wall surface inside the wiring grooves 31 to 37. A barrier insulation layer 8 by SiC, SiN, SiOC is interposed between the first insulation film 1 and the second insulation film 2. Each of the metal wirings faces the second insulation film 2.

In the apparatus of this invention, a structure of the first insulation film comprising the silicon oxide film is a silicon oxide film structure subjected to moisture absorption limitation. That is, this silicon oxide film is comprised of a silicon oxide film with a characteristic showing that a ratio S_{I}/S_{II} of area integrations of S_{I} and S_{II} of a desorption gas spectrum at temperatures of 0 to 450° C. by ion current measurement of the temperature programmed desorption mass analysis measurement based on mass 18 relating to the lamination structure of silicon oxide film and organic insulation film, and a single layer structure of silicon oxide film is not less than 1 or not more than 1.5.

That is, the formation of silicon film is performed under film formation condition for forming such silicon oxidation.

That is, the manufacturing method of the present invention is for producing the apparatus of the invention explained with reference to FIG. 1, for example, and comprises a film forming step of a first insulation film comprising a silicon oxide film by chemical vapor deposition (CVD), and a film forming step of a second insulation film by the organic insulation film, but when the film of the first insulation film is formed by plasma CVD by a parallel flat-plate apparatus, the film is formed under a film forming condition that specific moisture absorption is limited.

That is, a laminated structure of silicon oxide film and organic insulation film, and a single layer structure of silicon oxide film are previously formed by a film forming apparatus which forms the film, and of these, as mentioned before, a condition that the area integration ratio S_{I}/S_{II} of a desorption gas spectrum by ion current measurement of the temperature programmed desorption mass analysis measurement based on mass 18 is not less than 1 or not more than 1.5 is obtained, and a silicon oxide film constituting the first insulation film 1 is formed under this condition.

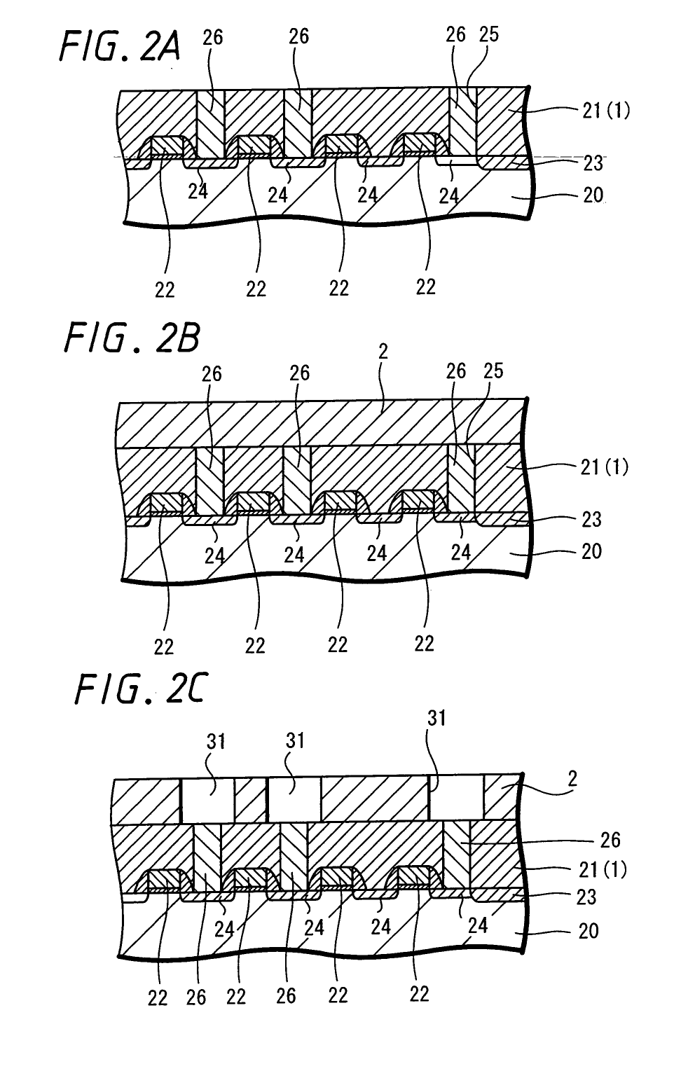

One example of the manufacturing procedure of the semiconductor device shown in FIG. 1 will be explained with reference to the schematic sectional views in respective processes of FIGS. 2 to 5. In FIGS. 2 to 5, portions corresponding to FIG. 1 are attached with the same symbols.

As shown in FIG. 2A, on the semiconductor substrate 20 having the above-described structure, the on-substrate insulation layer 21 is formed of, e.g. the first insulation film 1. A through hole 25 is formed in the semiconductor circuit element 22, e.g. a predetermined S/D region 24 of MOS from which a conductive plug of the on-substrate insulation layer 21 is pulled out by means of pattern etching or the like. For example, conductive plug 26 by tungsten (W) is charged and formed into the through hole 25 by a known method. That is, tungsten is buried into the through hole 25 by the CVD method, it is polished by CMP (Chemical Mechanical Polish) from its surface, the plug 26 formed of tungsten is buried in the through hole 25, and its upper end is formed into such a flat surface that the upper end is flush with a surface of the interlayer insulation layer 21.

The second insulation film 2 made of organic insulation film having low specific inductivity k is formed on the on-substrate insulation layer 21 as shown in FIG. 2B.

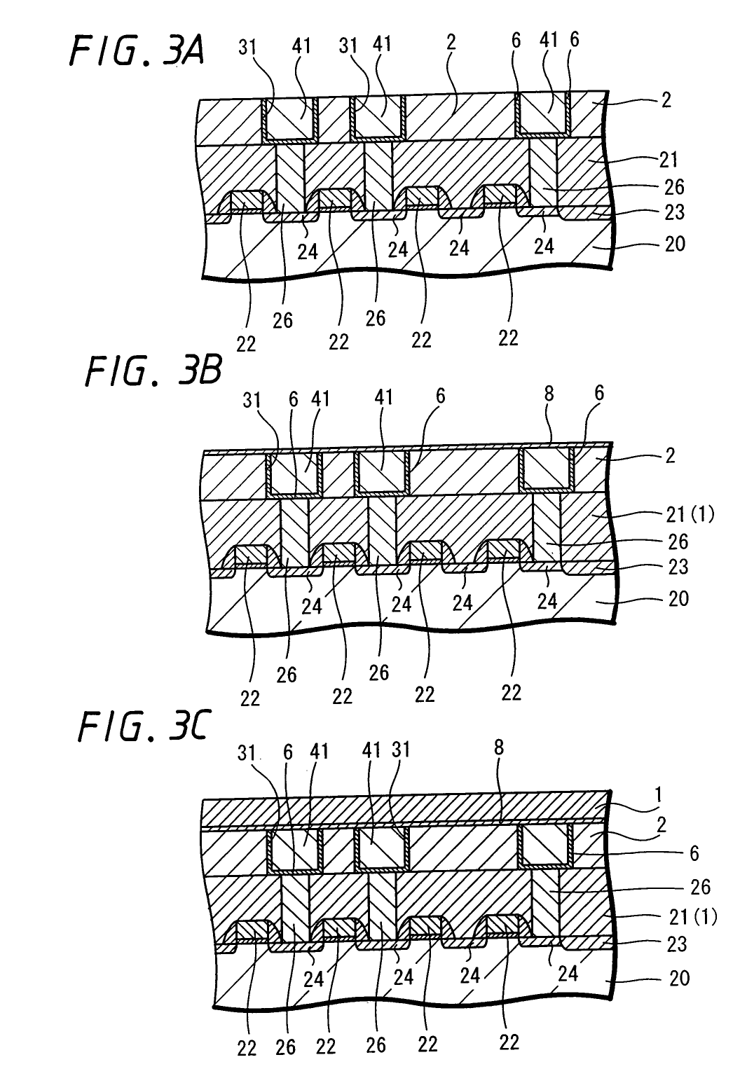

As shown in FIG. 2C, a first wiring groove 31 for forming a first metal wiring having a predetermined pattern which is in contact with a required conductive plug 26 shown in FIG. 3A is formed.

The wiring groove 31 is formed such that using photolithography technique, an etching mask is formed of, e.g. photoresist in which a pattern opening of a wiring groove to be formed is formed, etching having such a depth that corresponds to the entire thickness of the second insulation film 2 is carried out with respect to the second insulation film 2 by RIE (reactive ion etching) through this opening of this mask.

In this manner, the first wiring groove 31 of a. predetermined pattern is formed straddling a predetermined conductive plug 26.

As shown in FIG. 3A, first metal wiring 41 made of Cu is charged into the wiring groove 31. When this metal wiring 41 is metal which is prone to be dispersed like the Cu, a barrier metal layer 6 made of TaN or TiN having dispersion preventing effect is formed on an inner surface of the wiring groove 31 by anisotropic sputtering, for example, before charging the metal wiring 41.

Thereafter, e.g. Cu is formed by sputtering or CVD method to entirely bury the wiring groove 31, and this Cu is subjected to re-melting at 400° C., i.e. reflow and sintering so as to flatten the surface thereof. Then, the CMP is carried out from its surface, Cu is selectively allowed to remain only in the wiring groove 31, thereby forming the first metal wiring 41, and the surface thereof forms a flat surface that is substantially flush with the surface of the second insulation film 2.

Next, as shown in FIG. 3B, when the metal wiring 41 is formed of Cu entirely on the second insulation film 2 that is faced by the metal wiring 41, a barrier insulation layer 8 made of SiC, SiN, SiOC or the like is formed on the entire surface in order to restrain its dispersion.

Thereafter, as shown in FIG. 3C, the first insulation film 1 made of the same material as that of the first insulation film 1 in the above-described interlayer insulation layer 21 is formed of, e.g. oxide silicon film on the barrier insulation layer 8 with the same method, e.g., the CVD method.

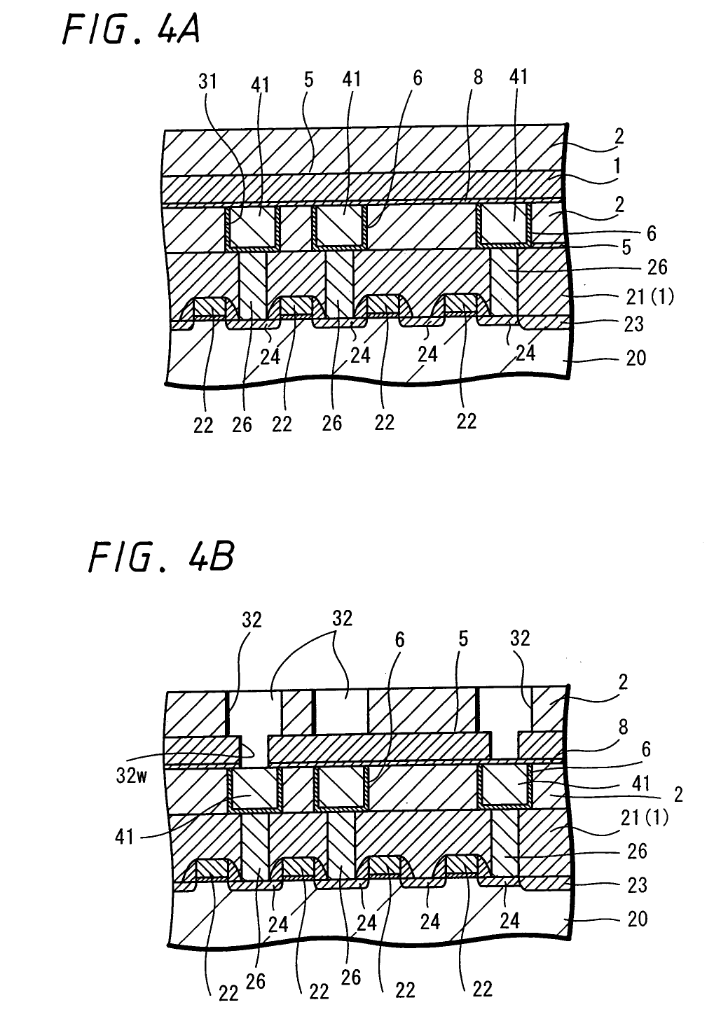

Next, as shown in FIG. 4A, the second insulation film 2 made of organic film having low specific inductivity is formed on the first insulation film.

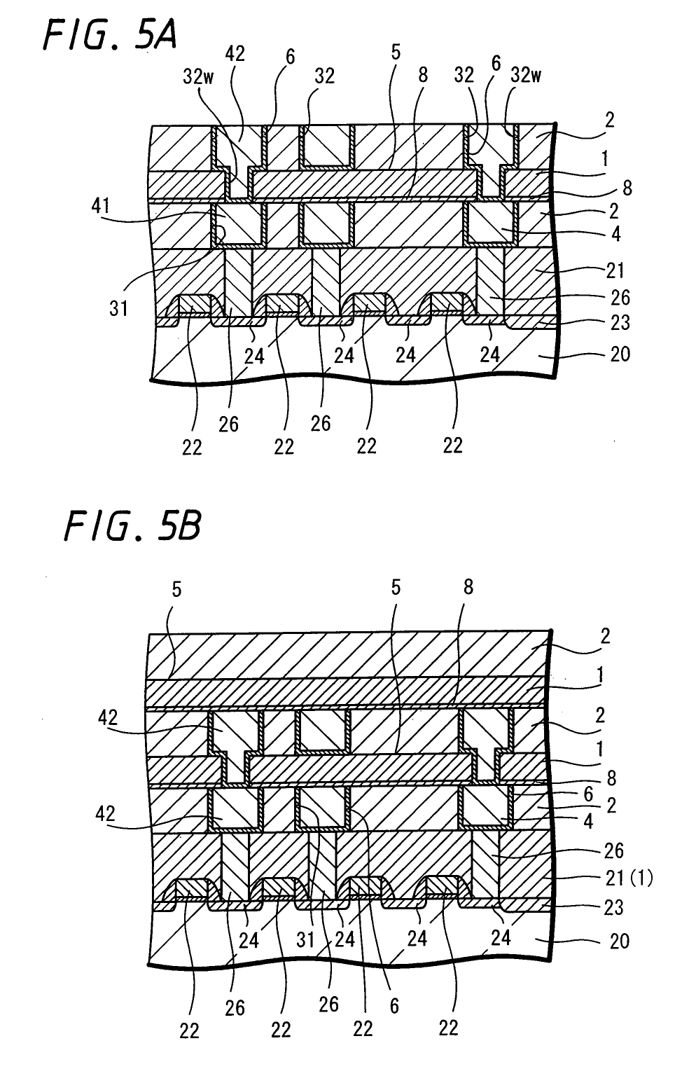

Next, as shown in FIG. 4B, a second wiring groove 32 having a pattern of the second metal wiring 42 having a predetermined pattern shown in FIG. 5A is formed on the laminated interlayer insulation film made of the first insulation film 1 and the second insulation film 2.

The second wiring groove 32 has the through hole 32w, which passes through the first insulation film 1, bored only at a portion that comes into contact with the lower first metal wiring 41, and has it bored at any other portion of the second insulation film 2 with low specific inductivity.

That is, in this case, pattern etching by required RIE using the photolithography technique is performed across the entire depth of the second insulation film 2 in the same way as explained in, e.g. FIG. 2C.

Then, at a portion where the through hole 32w is formed, an etching mask made of photoresist having an opening by the photolithography is formed, and a through hole is formed by the RIF via this opening.

In this wiring groove 32, the second insulation film 2 formed of low specific inductivity film is formed wide in width whose groove distance is narrow, but a groove distance of the through hole 32w in the first insulation film 1 having high specific inductivity for forming a double-wiring-type groove can be increased by reducing a width thereof.

As shown in FIG. 5A, the second metal wiring 42 is formed by being charged into the second wiring groove 32, and its surface is flattened.

The metal wiring 42 can be formed and flattened with the same method as explained in FIG. 3A.

As shown in FIG. 5B, when the metal wiring 41 similar to that explained in FIGS. 3B to 4A is made of Cu, in order to restrain its dispersion, a barrier insulation laver 8 made of SiC, SiN, SiOC or the like is formed on the entire surface.

Then, the first insulation film 1 is formed on the entire surface of the barrier insulation layer 8 in the same manner as described above, and the second insulation film 2 made of organic insulation film with low specific inductivity is formed.

In this manner, the forming operation of the third to seventh wiring grooves 33 to 37, the forming operation of the barrier metal layer 6, the forming operation of the metal wirings 43 to 47 and the forming operation of the barrier insulation layer 8 are repeated as shown in FIG. 1, thereby forming the desired number of multi-layer wiring structures, i.e., seven multi-layer wiring structures in the example shown in FIG. 1. Although not illustrated in the drawings, a surface insulation layer, an terminal electrode and the like are formed on the upper most layer thereof.

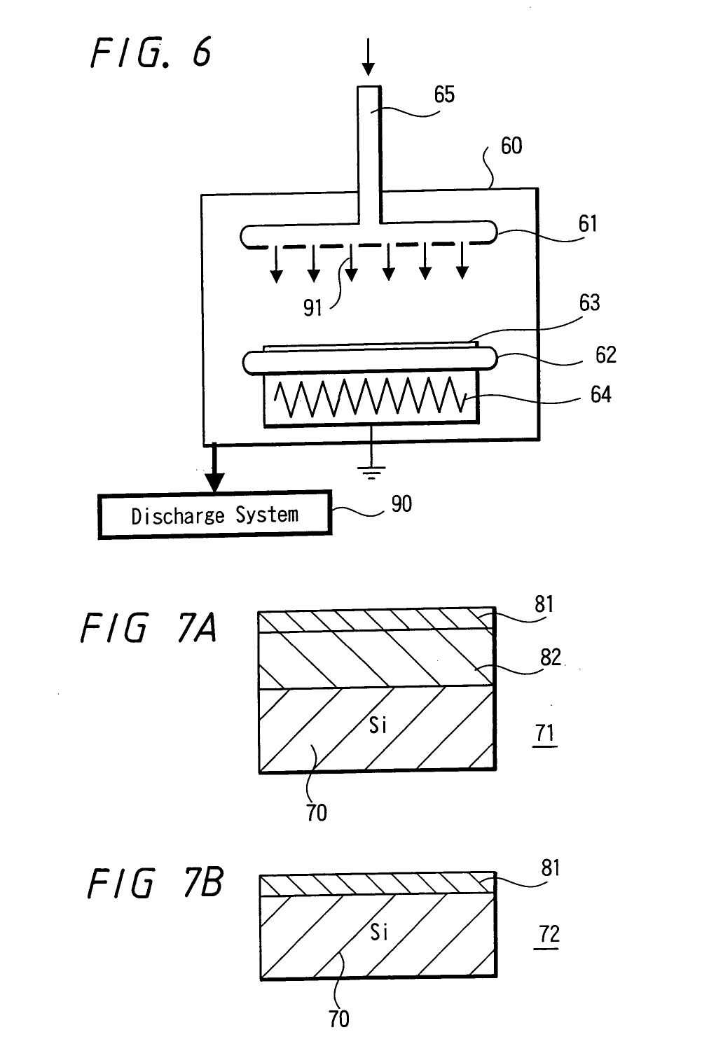

A method for forming the above-described first insulation film 1 according to the manufacturing method of the present invention will be explained in detail. The film is formed by the parallel flat-plate type plasma CVD apparatus whose structure is shown in FIG. 6 for example.

This film forming apparatus is a known apparatus. This apparatus has a reaction chamber 60 connected to a discharge system 90, and an upper electrode 61 and a lower electrode 62 of the parallel flat-plate electrodes are disposed opposing to each other in the reaction chamber 60.

A body to be filmed 63 is disposed on the lower electrode 62.

A heater 64 is disposed below the lower electrode 62, and if the heater 64 is energized, the lower electrode 62 and thus the body to be filmed 63 is heated to a predetermined temperature.

The reaction chamber 60 is provided with a supply opening 65 for row material gas, and row material gas 91 is uniformly dispersed and supplied toward the body to be filmed 63 from a gas dispersing opening of the upper electrode 61 having a shower structure.

RF (high frequency) electricity is applied between the upper electrode 61 and the lower electrode 62.

A film is formed using this apparatus, but in this invention, a laminated structure (sample 1, hereinafter) of silicon oxide film and organic insulation film, as well as a single layer structure of silicon oxide film (sample 2, hereinafter) are formed.

As shown in FIGS. 7A and 7B which are schematic sectional views, on a silicon-substrate 70, in the sample 1, an organic insulation film 82 constituting the second insulation film 2 is formed, a silicon oxide film 81 constituting the first insulation film 1 is formed, and in the sample 2, a silicon oxide film 81 constituting the first insulation film 1 is formed.

Embodiments thereof will be explained below. Embodiments 1 and 2 show a case in which using SiLK-J produced by Dow Chemical Co. of low specific inductivity film as the organic insulation film 82 of the sample 1, the forming condition of the silicon oxide film 81 is stipulated such that S_{I}/S_{II}≦1.4 is obtained.

An embodiment 3 shows a case in which using FLARE produced by Aligned Signal Co. of low specific inductivity film as the organic insulation film 82 of the sample 1, the forming condition of the silicon oxide film 81 is stipulated such that S_{I}/S_{II}≦1.5 is obtained.

[Embodiment 1]

In this embodiment, an organic insulation film 82 made of SiLK-J produced by Dow Chemical Co. of low specific inductivity film of 300 nm thickness was formed on silicon-substrate 70, and a silicon oxide SiO film 81 of 100 nm thickness was formed thereon by the parallel flat-plate type plasma CVD apparatus, thereby forming a sample 1.

On the silicon-substrate 70, a silicon oxide SiO film 81 of 100 nm thickness was formed by the parallel flat-plate type plasma CVD apparatus, thereby forming a sample 2.

A Forming conditions of SiO film were selected in the following manner.

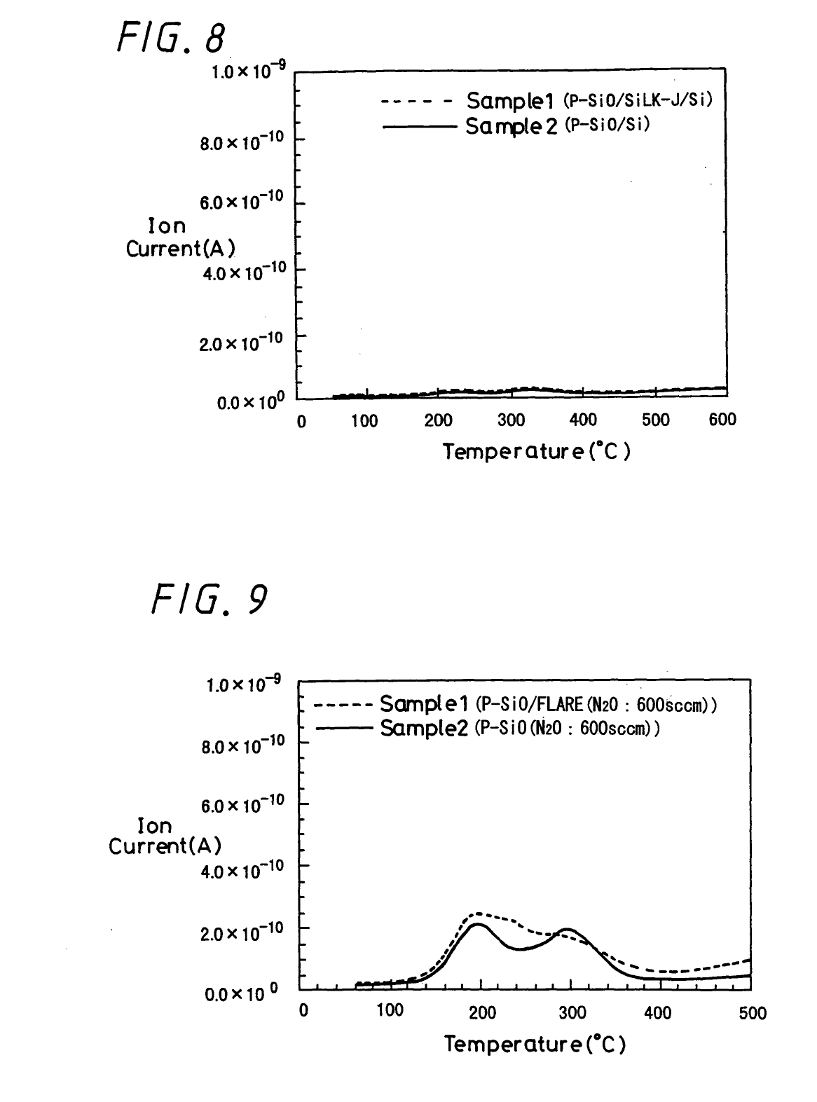

FIG. 8 shows a desorption gas spectrums of samples 1 and 2 by temperature programmed desorption mass analysis measurement (TWA1000S) of mass 18 (H₂O amount). In FIG. 8, a broken curved line shows a desorption gas spectrum of sample 1, a solid curved line shows a desorption gas spectrum of the sample 2, and an area integration ratio S_{I}/S_{II} at 0° C. to 450° C. by both the curved lines was 1.1.

Film forming conditions of the above-described SiO were as follows:

N₂ gas flow amount: 1000 scam

N₂O gas flow amount: 500 scam

SiH₄ gas flow amount: 110 scam

pressure: 665 Pa

RF electricity: 350W

film forming substrate temperature: 400° C.

A first insulation film of a semiconductor device of multi-layer wiring structure in which the first to seven metal wirings in FIG. 1 were laminated was formed, and the second insulation film 2 was formed of organic insulation film of SiLK-J.

At that time, a semiconductor device having a reliable multi-layer wiring structure in which no crack was generated and peeling of film was not generated at all could be formed. If crack was generated, it could be observed visually.

Next, N₂O gas flow amount and SiH₄ gas flow amount in the above example 1 were changed.

[Embodiment 2]

The method was the same as that of the example 1, but the film forming condition of SiO₂ was set as follows:

N₂ gas flow amount: 1000 sccm

N₂O gas flow amount: 500 scam

SiH₄ gas flow amount: 100 scam

pressure: 665 Pa

RF electricity: 350W

film forming substrate temperature: 400° C.

FIG. 9 shows a desorption gas spectrums of the samples 1 and 2 by temperature programmed desorption mass analysis measurement of mass 18 (H₂O amount). In FIG. 9, a broken curved line shows a desorption gas spectrum of sample 1, a solid curved line shows a desorption gas spectrum of the sample 2, and an area integration ratio S_{I}/S_{II} at 0° C. to 450° C. by both the curved lines was 1.0.

A first insulation film of a semiconductor device of multi-layer wiring structure in which the first to seven metal wirings in FIG. 1 were laminated was formed, and the second insulation film 2 was formed of organic insulation film of SiLK-J.

In this case also, a semiconductor device having a reliable multi-layer wiring structure in which no crack was generated and peeling of film was not generated at all could be formed.

[Embodiment 3]

The method was the same as that of the example 1, but the film forming condition of SiO₂ was set as follows:

N₂ gas flow amount: 1000 sccm

N₂O gas flow amount: 500 sccm

SiH₄ gas flow amount: 100 sccm

pressure: 665 Pa

RF electricity: 350W

film forming substrate temperature: 400° C.

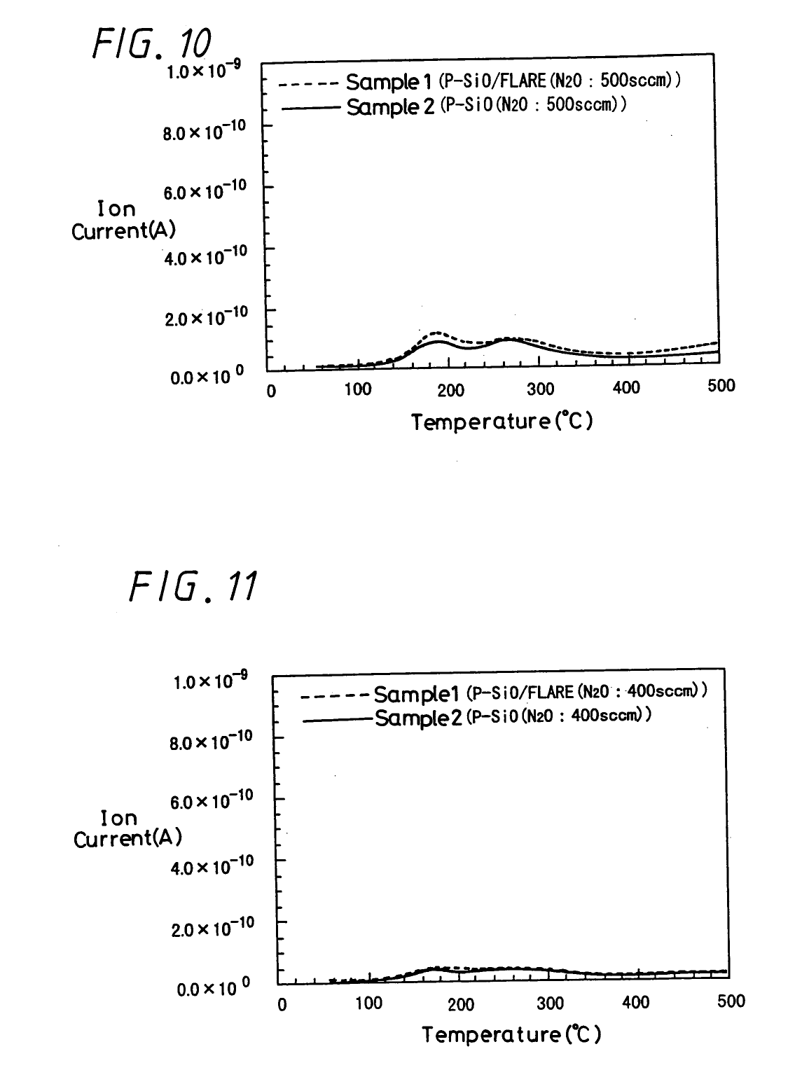

FIG. 10 shows a desorption gas spectrums of the samples 1 and 2 by temperature programmed desorption mass analysis measurement of mass 18 (H₂O amount). In FIG. 10, a broken curved line shows a desorption gas spectrum of sample 1, a solid curved line shows a desorption gas spectrum of the sample 2, and an area integration ratio S_{I}/S_{II} at 0° C. to 450° C. by both the curved lines was 1.5.

A first insulation film of a semiconductor device of multi-layer wiring structure in which the first to seven metal wirings in FIG. 1 were laminated was formed, and the second insulation film 2 was formed of organic insulation film of SiLK-J.

In this case also, a semiconductor device having reliable multi-layer wiring structure in which no crack was generated and peeling of film was not generated at all could be formed.

[Embodiment 4]

The method was the same as that of the example 1, but the film forming condition of SiO₂ was set as follows.

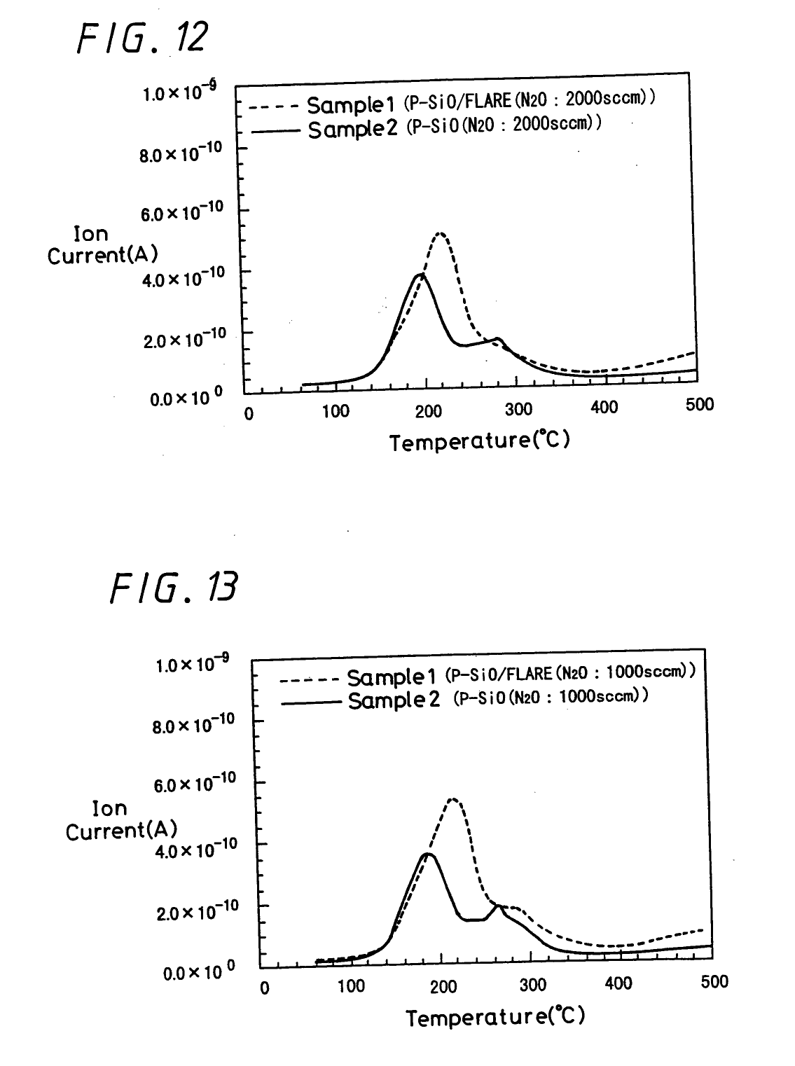

FIG. 11 shows a desorption gas spectrums of the samples 1 and 2 by temperature programmed desorption mass analysis measurement of mass 18 (H₂O amount). In FIG. 11, a broken curved line shows a desorption gas spectrum of sample 1, a solid curved line shows a desorption gas spectrum of the sample 2, and an area integration ratio S_{I}/S_{II} at 0° C. to 450° C. by both the curved lines was 1.3.

A first insulation film of a semiconductor device of multi-layer wiring structure in which the first to seven metal wirings in FIG. 1 were laminated was formed, and the second insulation film 2 was formed of organic insulation film of SiLK-J.

In this case also, a semiconductor device having reliable multi-layer wiring structure in which no crack was generated and peeling of film was not generated at all could be formed.

[Embodiment 5]

In this example also, an organic insulation film 82 of 300 nm thickness by SiLK-J produced by Down Chemical Co. of low specific inductivity film was formed on a silicon-substrate 70, and a silicon oxide film 81 of 100 nm thickness was formed of SiO by the above-described parallel flat-plate type plasma CVD apparatus, thereby forming a sample 1.

Further, a silicon oxide film 81 of 100 nm thickness formed of SiO by the parallel flat-plate type plasma CVD apparatus was formed on the silicon-substrate 70,. thereby forming a sample 2.

Forming conditions of SiO film were selected as follows. At that time, S_{I}/S_{II} at 0 to 450° C. was 1.0.

Forming conditions of SiO film were as follows:

N₂ gas flow amount: 4500 sccm

N₂O gas flow amount: 400 sccm

SiH₄ gas flow amount: 90 sccm

pressure: 665 Pa

RF electricity: 530W

film forming substrate temperature: 350° C.

A first insulation film of a semiconductor device of multi-layer wiring structure in which the first to seven metal wirings in FIG. 1 were laminated was formed, and the second insulation film 2 was formed of organic insulation film of SILK-J.

In this case also, a semiconductor device having reliable multi-layer wiring structure in which no crack was generated and peeling of film was not generated at all could be formed.

### COMPARATIVE EXAMPLES 1 to 3

In these comparative examples 1 to 3, N₂O gas flow amounts in the example 2 were respectively set to 2000, 1000 and 800 sccm.

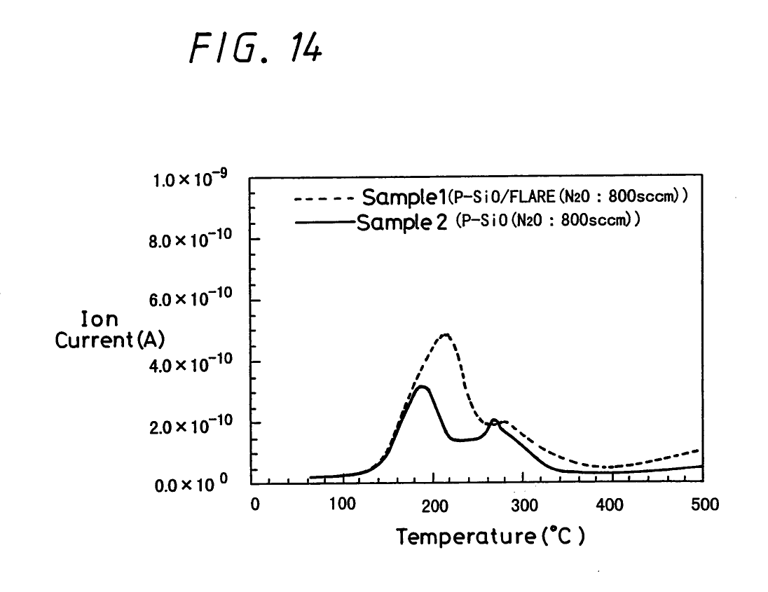

In FIG.12 . FIG.14, similar desorption gas spectrums of respective samples 1 and 2 of each of those comparative examples 1, 2, 3 are shown with a broken line and solid curve line, respectively

The S_{I}/S_{II} of the comparative examples 1 to 3 are, 1.8, 1.8 and 1.7, respectively.

Under the film forming conditions of SiO of these comparative examples, a first insulation film of a semiconductor device of a multi-layer wiring structure in which the first to seventh metal wirings shown in FIG. 1 were laminated was formed, and a second insulation film 2 was formed of organic insulation film of SiLK-J.

At that time, crack was generated and the film was peeled off.

As apparent from the embodiments 1 to 5 and the comparative examples 1 to 3, moisture absorption can be controlled by selection of conditions such as the amount of N₂O gas and SiH₄ gas to be supplied, for example.

[Embodiment 6]

In this embodiment, an organic insulation film 82 of 300 nm thickness was formed of FLARE produced by Allied signal Co. of low specific inductivity film on a silicon-substrate 70, and a silicon oxide film 81 of 100 nm thickness made of SiO was formed thereon by the above-described parallel flat-plate type plasma CVD apparatus, thereby forming a sample 1.

A silicon oxide film 81 of 100 nm made of SiO was formed on the silicon-substrate 70 by the parallel flat-plate type plasma CVD apparatus, thereby forming a sample 2.

Forming conditions of SiO film were selected as follows:

Forming conditions of SiO film were as follows:

N₂ gas flow amount: 4500 sccm

N₂O gas flow amount: 400 sccm

SiH₄ gas flow amount: 90 sccm

pressure: 665 Pa

RF electricity: 530W

film forming substrate temperature: 350° C.

The area integration ratio S_{I}/S_{II} of a desorption gas spectrums samples 1 and 2 by the temperature programmed desorption mass analysis measurement of mass 18 (H₂O amount) at 0 to 450° C. was 1.0.

Forming conditions of the above-described SiO film were as follows.

The first insulation film by multi-layer wiring structure in which the first to seventh metal wirings shown in FIG. 1 were laminated was formed under the forming condition of the SiO film, and a second insulation film 2 was formed of organic insulation film of SiLK-J.

At that time, a semiconductor device having reliable multi-layer wiring structure in which no crack was generated and peeling of film was not generated at all could be formed.

As apparent from the above fact, the generation of crack was reliably avoided at S_{I}/S_{II}≦1.5.

As described above, in this invention, by making the first insulation film 1 of silicon oxide film to be comprised of silicon oxide film which is subjected to moisture absorption limitation having a characteristic that shows a ratio S₁/S₁₁ of area integration S₁ and S₁₁ of a desorption gas spectrum is not less than 1 or not more than 1.5, even when the first insulation film has such a lamination structure, and the second insulation film is made of organic insulation film, it is possible to avoid the lowering of reliability due to desorption of gas. Thus, even if at least a portion of the multi-layer wiring structure is formed of organic insulation film of low specific inductivity, and parasitic capacitance between wirings is reduced, a reliable semiconductor device can be produced with excellent yield.

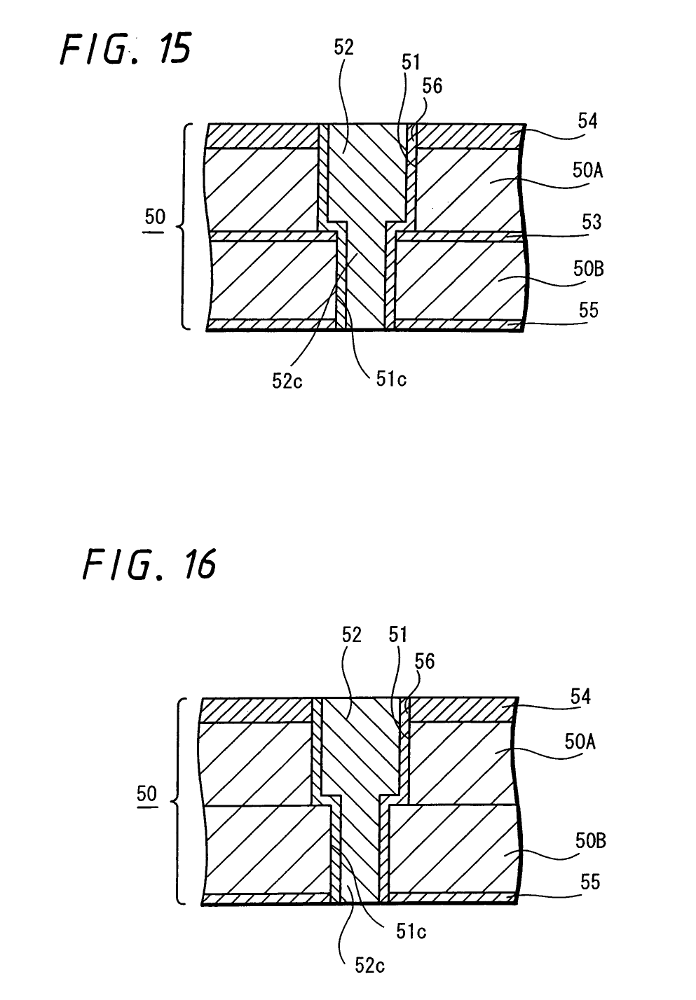

Although the above example is of hybrid structure, in a so-called full low specific inductivity structure as explained with reference to FIG. 15, the present invention can also be applied to various structure having a laminated structure of silicon oxide film such as stopper layer and organic insulation film, the invention can be variously modified within a range of the invention, and embodiments can be varied in accordance with the modification of course.

According to the apparatus of this invention, as described above, in the laminated structure of the silicon oxide film and organic insulation film, the silicon oxide film is set in such a manner that moisture absorption is limited by specifying characteristics, e.g. a ratio S_{I}/S_{II} of area integrations S_{I} and S_{II} of a desorption gas spectrum by ion current measurement of the temperature programmed desorption mass analysis measurement, thereby making it possible to effectively avoid deterioration in characteristics of the organic insulation film and metal wiring, i.e., degeneration or peeling off, and highly reliable a desorption gas spectrum can be formed.

In the manufacturing method of the present invention, it is possible to effectively avoid deterioration in characteristics of the organic insulation film and metal wiring, i.e., degeneration or peeling off, by selecting film forming conditions capable of obtaining the above-described condition in the film formation of silicon oxide film, and a highly reliable semiconductor device can be produced with excellent yield.

Therefore, according to the present invention, since organic insulation film of low specific inductivity can be used as an insulation layer, it is possible to use metal wire made of Cu having excellent conductivity without lowering parasitic capacitance between wirings and deteriorating the characteristics, and it is possible to produce a semiconductor device having high density and high speeds.

1. A semiconductor device formed of an insulation layer having at least a laminated portion in which a first insulation film made of silicon oxide film and a second insulation film made of organic insulation film are laminated on each other, wherein
said semiconductor device has a silicon oxide film structure in which moisture absorption is limited, said structure having characteristics that a ratio S_{I}/S_{II} of area integrations S_{I} and S_{II} of a desorption gas spectrum at temperatures of 0° to 450° C. by ion current measurement of the temperature programmed desorption mass analysis measurement based on mass 18 relating to the laminated structure of the silicon oxide film and the organic insulation film and a single layer structure of the silicon oxide film is not less than 1 or not more than 1.5.

2. The semiconductor device according to claim 1, further comprising a multi-layer wiring structure having an insulation layer in which the first insulation film made of silicon oxide film and the second insulation film made of the organic insulation film are laminated on each other, and a metal wiring made of Cu.

3. A manufacturing method of a semiconductor device comprising
a film forming step of a first insulation film made of silicon oxide film by a chemical vapor deposition (CVD); and
a film forming step of a second insulation film made of organic insulation film, wherein
said first insulation film is formed under film forming condition that a ratio S_{I}/S_{II} of area integrations S_{I} and S_{II} of a desorption gas spectrum at temperatures of 0. to 450. C. by ion current measurement of the temperature programmed desorption mass analysis measurement based on 18 relating to the laminated structure of the silicon oxide film and the organic insulation film and a single layer structure of the silicon oxide film is not less than 1 or not more than 1.5.

4. The manufacturing method of a semiconductor device according to claim 3, further comprising a multi-layer wiring structure having an insulation layer in which the first insulation film made of silicon oxide film and the second insulation film made of the organic insulation film are laminated on each other, and a metal wiring made of Cu.
